(19) United States
(12) Patent Application Publication
(10) Pub. No.: US 2019/0035870 A1
(43) Pub. Date: Jan. 31, 2019

(54) SUBSTRATE FOR DISPLAY APPARATUS, ORGANIC LIGHT EMITTING DISPLAY APPARATUS, AND MANUFACTURING METHOD THEREOF

(71) Applicant: Samsung Display Co., Ltd., Yongin-si (KR)

(72) Inventors: Sangjin Park, Yongin-si (KR); Youngdae Kim, Yongin-si (KR); Heena Kim, Yongin-si (KR); Yonghwan Ryu, Yongin-si (KR); Taehyeok Choi, Yongin-si (KR); Euikang Heo, Yongin-si (KR)

(21) Appl. No.: 15/860,515

(22) Filed: Jan. 2, 2018

(30) Foreign Application Priority Data
Jul. 28, 2017 (KR) 10-2017-0096377

(51) Int. Cl. H01L 27/32

(52) U.S. Cl. CPC H01L 27/3265; H01L 2227/323; H01L 27/3276; H01L 27/3262

(57) ABSTRACT

A substrate for a display apparatus includes a substrate, and a capacitor on a first surface of the substrate. The capacitor includes a first electrode, a second electrode facing the first electrode, and a dielectric layer between the first electrode and the second electrode. Here, the substrate has a first hole penetrating through the substrate in an area corresponding to a part of the first electrode of the capacitor, and a first conductive material is in the first hole.

### CROSS-REFERENCE TO RELATED APPLICATION

This application claims priority to and the benefit of Korean Patent Application No. 10-2017-0096377, filed on Jul. 28, 2017, in the Korean Intellectual Property Office, the disclosure of which is incorporated herein in its entirety by reference.

### BACKGROUND

### 1. Field

One or more embodiments relate to a substrate (substrate apparatus) for a display apparatus, an organic light-emitting display apparatus, and a manufacturing method thereof.

### 2. Description of the Related Art

An organic light-emitting display apparatus includes a plurality of pixels, each of the pixels including an organic light-emitting diode that is a self-emission device. Each pixel includes a plurality of thin film transistors for driving the organic light-emitting diode, and one or more capacitors. As demand for ultrahigh resolution increases, a display apparatus may have difficulty in securing a sufficient capacitor area for its capacitors.

### SUMMARY

One or more aspects of embodiments are directed toward a substrate and a display apparatus that may increase an area of a capacitor without being affected by an area of a display.

Additional aspects will be set forth in part in the description which follows and, in part, will be apparent from the description, or may be learned by practice of the presented embodiments.

According to one or more embodiments, a substrate apparatus for a display apparatus includes a substrate, and a capacitor on a first surface of the substrate. The capacitor includes a first electrode, a second electrode facing the first electrode, and a dielectric layer between the first electrode and the second electrode. Here, the substrate has a first hole penetrating through the substrate in an area corresponding to a part of the first electrode of the capacitor, and a first conductive material is in the first hole.

The substrate apparatus may further include a first pattern layer and a second pattern layer on the first surface of the substrate, the first pattern layer being at a same level as the first electrode of the capacitor and the second pattern layer being at a same level as the second electrode of the capacitor, wherein the substrate further has a second hole penetrating through the substrate in an area corresponding to a part of each of both end portions of the first pattern layer, and a second conductive material is in the second hole.

The first pattern layer may include a semiconductor material.

The substrate apparatus may further include an insulating layer between the first pattern layer and the second pattern layer, wherein the insulating layer includes a material that is the same as or different from the dielectric layer of the capacitor.

The substrate apparatus may further include an active layer on the first surface of the substrate at a same level as the first electrode of the capacitor, a gate electrode over the active layer, and a source electrode and a drain electrode connected to both end portions of the active layer, respectively.

The substrate apparatus may further include a protection layer covering the capacitor.

According to one or more embodiments, an organic light-emitting display apparatus includes a substrate, a capacitor on a first surface of the substrate (the capacitor including a first electrode, a second electrode facing the first electrode, and a dielectric layer between the first electrode and the second electrode), and a first thin film transistor on a second surface, opposite to the first surface, of the substrate. The first thin film transistor includes a first active layer, a first gate electrode, and a first source electrode and a first drain electrode connected to both end portions of the first active layer, respectively. Here, the substrate has a first hole penetrating through the substrate in an area corresponding to a part of the first electrode of the capacitor, and a first conductive material is in the first hole, wherein the organic light-emitting display apparatus further comprises a connection electrode electrically connecting one of the first source electrode and the first drain electrode of the first thin film transistor to the first conductive material in the substrate.

The connection electrode may extend from the one of the first source electrode and the first drain electrode of the first thin film transistor.

The capacitor may overlap at least a part of the first thin film transistor.

The organic light-emitting display apparatus may further include a second thin film transistor including, on the first surface of the substrate, a second active layer at a same level as the first electrode of the capacitor and a second gate electrode at a same level as the second electrode of the capacitor, and on the second surface of the substrate, a second source electrode and a second drain electrode connected to both end portions of the second active layer, respectively, wherein the substrate includes a second hole penetrating through the substrate in an area corresponding to a part of each of both end portions of the second active layer, and a second conductive material in the second hole, wherein the second source electrode and the second drain electrode come in contact with the second conductive material.

The organic light-emitting display apparatus may further include an insulating layer between the second active layer and the second gate electrode, wherein the insulating layer includes a material that is the same as or different from the dielectric layer of the capacitor.

The organic light-emitting display apparatus may further include a third thin film transistor including, on the first surface of the substrate, a third active layer at a same level as the first electrode of the capacitor, a third gate electrode at a same level as the second electrode of the capacitor, and a third source electrode and a third drain electrode connected to both end portions of the third active layer, respectively,

The organic light-emitting display apparatus may further include an emission device arranged above the first thin film transistor and including a first electrode, a second electrode facing the first electrode, and an organic light-emitting layer between the first electrode and the second electrode.

According to one or more embodiments, a method of manufacturing an organic light-emitting display apparatus includes preparing a substrate, forming, on a first surface of the substrate, a capacitor including a first electrode, a second electrode facing the first electrode, and a dielectric layer between the first electrode and the second electrode, reversing the substrate, and forming a first hole penetrating through the substrate in an area corresponding to a part of the first electrode of the capacitor, and filling a first conductive material in the first hole.

The first hole may be formed by a laser drill technique.

The method may further include forming, on a second surface, opposite to the first surface, of the substrate, a first thin film transistor including a first active layer, a first gate electrode, and a first source electrode and a first drain electrode connected to both end portions of the first active layer, respectively; and forming a connection electrode connecting one of the first source electrode and the first drain electrode of the first thin film transistor to the first conductive material in the substrate.

The method may further include forming, on the first surface of the substrate, a first pattern layer at a same level as the first electrode of the capacitor and a second pattern layer at a same level as the second electrode of the capacitor, reversing the substrate, and forming a second hole penetrating through the substrate in an area corresponding to a part of each of both end portions of the first pattern layer, and filling a second conductive material in the second hole.

The second hole may be formed by a laser drill technique.

The method may further include forming, on a second surface, opposite to the first surface, of the substrate, an electrode layer contacting each of both end portions of the first pattern layer.

The method may further include forming, on the first surface of the substrate, an active layer at a same level as the first electrode of the capacitor, a second gate electrode at a same level as the second electrode of the capacitor, and a source electrode and a drain electrode connected to both end portions of the active layer, respectively.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view schematically illustrating a substrate apparatus for a display apparatus according to an embodiment;

FIGS. 2A to 2E are cross-sectional views schematically illustrating a manufacturing process of the substrate apparatus of FIG. 1;

FIG. 3 is a cross-sectional view schematically illustrating an organic light-emitting display apparatus using the substrate apparatus of FIG. 1, according to an embodiment;

FIGS. 4A to 4E are cross-sectional views schematically illustrating a manufacturing process of the organic light-emitting display apparatus according to the embodiment illustrated in FIG. 3;

FIG. 5 is a cross-sectional view schematically illustrating a substrate apparatus for a display apparatus according to another embodiment;

FIGS. 6A to 6E are cross-sectional views schematically illustrating a manufacturing process of the substrate apparatus of FIG. 5;

FIG. 7 is a cross-sectional view schematically illustrating an organic light-emitting display apparatus using the substrate apparatus of FIG. 5;

FIG. 8 is a cross-sectional view schematically illustrating a substrate for a display apparatus according to another embodiment;

FIGS. 9A to 9D are cross-sectional views schematically illustrating a manufacturing process of the substrate apparatus of FIG. 8;

FIG. 10 is a cross-sectional view schematically illustrating a part of an organic light-emitting display apparatus using the substrate apparatus of FIG. 8;

FIGS. 11 and 12 are cross-sectional views schematically illustrating substrates for a display apparatus according to other embodiments; and

FIG. 13 is a graph showing a relationship between an increase in the area of a capacitor by calculation and the capacitance of the capacitor.

### DETAILED DESCRIPTION

Advantages and features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein.

Reference will now be made in detail to embodiments of the present disclosure, examples of which are illustrated in the accompanying drawings, wherein like reference numerals refer to the like elements throughout and redundant explanations are omitted.

It will be understood that although the terms “first,” “second,” etc. may be used herein to describe various components, these components should not be limited by these terms. These components are only used to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

Sizes of components in the drawings may be exaggerated for convenience of explanation. In other words, since sizes and thicknesses of components in the drawings are arbitrarily illustrated for convenience of explanation, the following embodiments are not limited thereto.

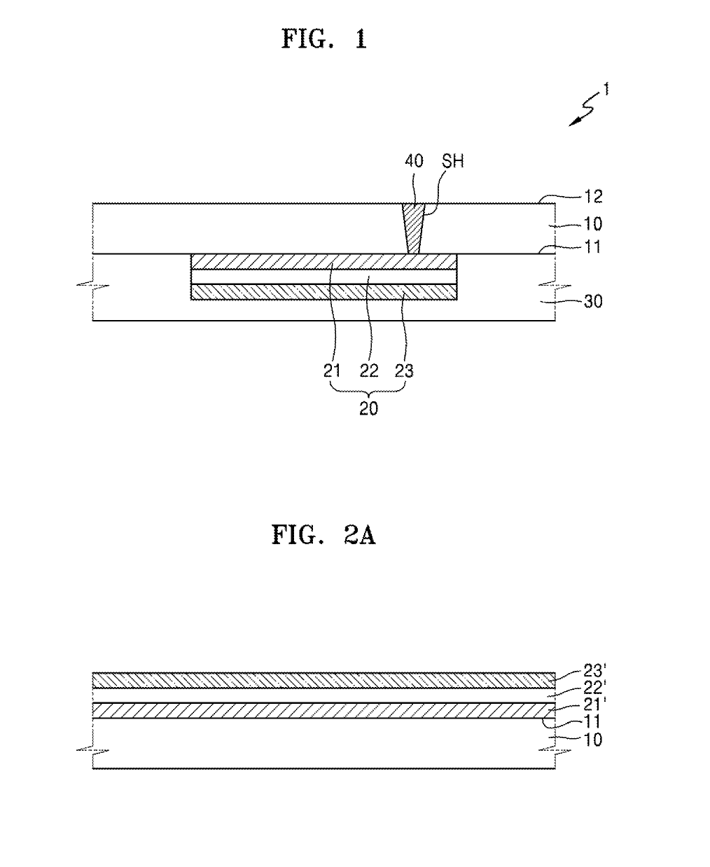

FIG. 1 is a cross-sectional view schematically illustrating a substrate apparatus 1 for a display apparatus according to an embodiment.

Referring to FIG. 1, the substrate apparatus 1 according to the present embodiment may include a substrate 10 and a capacitor 20 formed on (e.g., below) the first surface 11 of the substrate 10.

The capacitor 20 may include a first electrode 21 on the first surface 11 of the substrate 10, a second electrode 23 on the first electrode 21, and a dielectric layer 22 between the first electrode 21 and the second electrode 23. A protection layer 30 that entirely covers the first surface 11 of the substrate 10 may be provided over the capacitor 20 to, e.g., encapsulate the capacitor 20.

The substrate 10 may be a substrate having various materials such as a glass material, a plastic material, and/or a metal material.

The substrate 10 may have a hole SH for exposing a part of the first electrode 21 of the capacitor 20, and a conductive material 40 filling the hole SH. The conductive material 40 may electrically connect the capacitor 20 and circuit elements arranged on (e.g., above) a second surface 12 of the substrate 10.

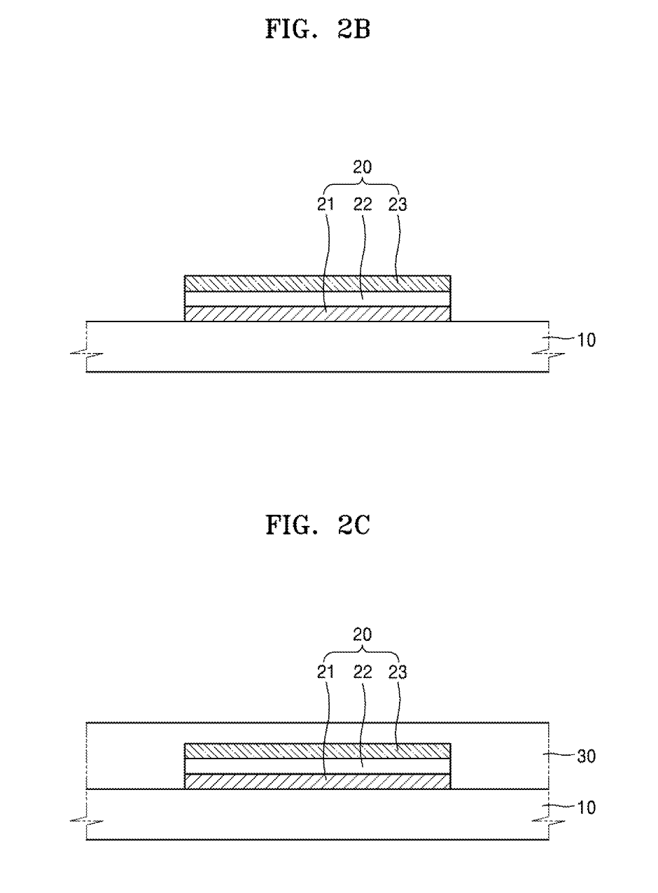

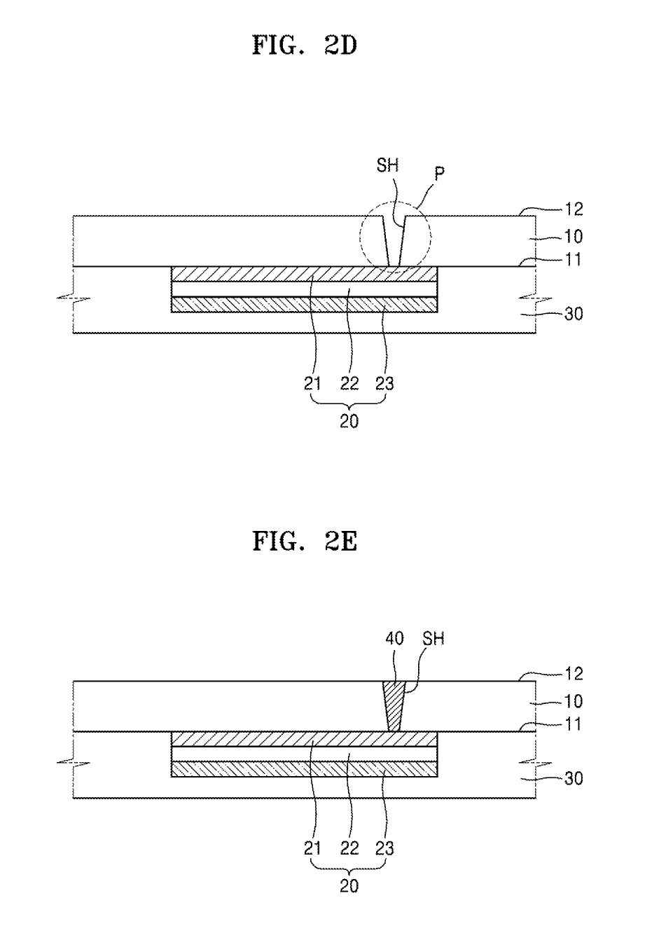

FIGS. 2A to 2E are cross-sectional views schematically illustrating a manufacturing process of the substrate apparatus 1 of FIG. 1.

Referring to FIG. 2A, the substrate 10 is prepared, and a first conductive layer 21′, a dielectric layer 22′, and a second conductive layer 23′ are sequentially deposited on the first surface 11 of the substrate 10. The dielectric layer 22′ may be configured with one insulating layer or two or more insulating layers.

Referring to FIG. 2B, the first conductive layer 21′, the dielectric layer 22′, and the second conductive layer 23′ are patterned. Accordingly, the capacitor 20 including the first electrode 21, the second electrode 23, and the dielectric layer 22 between the first electrode 21 and the second electrode 23 is formed.

Referring to FIG. 2C, the protection layer 30 is formed entirely over the first surface 11 of the substrate 10 where the capacitor 20 is formed.

The protection layer 30 may be formed in a single layer or a multilayer by a deposition and/or film lamination process using inorganic insulating material(s) and/or organic insulating material(s). The protection layer 30 may include a material that is the same as or different from the dielectric layer 22.

Referring to FIG. 2D, the substrate 10 is reversed, and the hole SH is formed in the substrate 10.

The hole SH may be formed by irradiating a laser beam in an area P of the second surface 12 of the substrate 10 that is reversed. The hole SH may be formed by using, for example, a laser drill technique. The laser drill technique uses various pulse lasers. The laser drill technique is a non-contact type process, and may form a fine hole pattern in the substrate 10 with a minimum or reduce allowance range compared to a machine drill technique. Furthermore, the laser drill technique does not need patterning and has a simple process. The hole SH may be formed with a certain diameter by penetrating through the substrate 10 to expose a part of the first electrode 21 of the capacitor 20.

Referring to FIG. 2E, the hole SH of the substrate 10 may be filled with the conductive material 40.

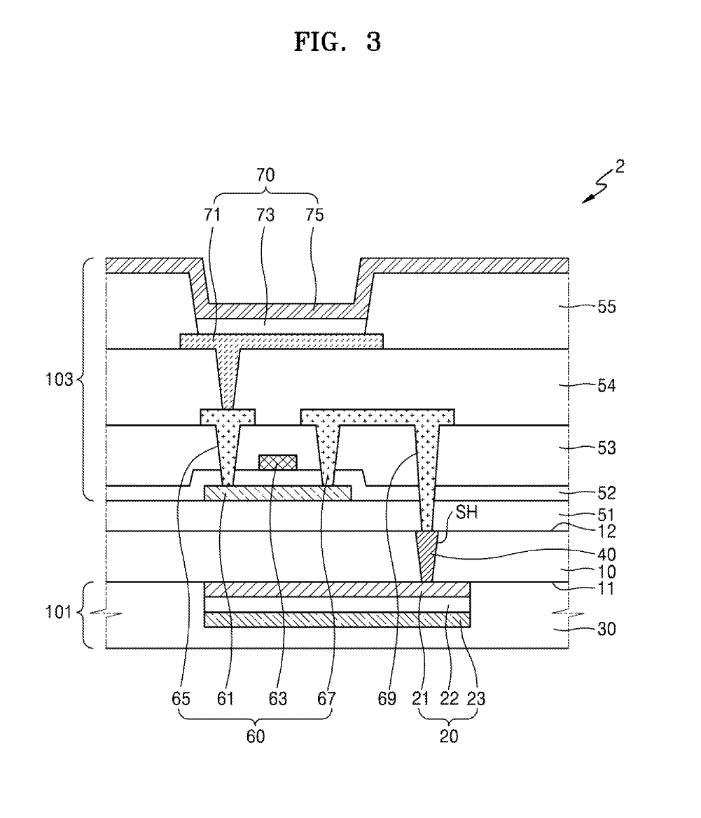

FIG. 3 is a cross-sectional view schematically illustrating an organic light-emitting display apparatus 2 using the substrate apparatus 1 of FIG. 1, according to an embodiment.

Referring to FIG. 3, the organic light-emitting display apparatus 2 according to the present embodiment may include the substrate 10, a first device layer 101 on the first surface 11 of the substrate 10, and a second device layer 103 on the second surface 12 of the substrate 10.

The substrate 10 may be provided with the hole SH and the conductive material 40 filling the hole SH. The conductive material 40 may electrically connect devices of the first device layer 101 and devices of the second device layer 103.

The first device layer 101 may include the capacitor 20.

The capacitor 20 may include the first electrode 21, the second electrode 23, and the dielectric layer 22 between the first electrode 21 and the second electrode 23. The protection layer 30 may be arranged over the capacitor 20.

The second device layer 103 may include a thin film transistor 60 and an emission device 70.

The thin film transistor 60 may include an active layer 61, a gate electrode 63 arranged to be insulated from the active layer 61, and a drain electrode 65 and a source electrode 67 respectively and electrically connected to a drain area and a source area of the active layer 61. A connection electrode 69 extending from the source electrode 67 of the thin film transistor 60 comes in contact with the conductive material 40, thereby electrically connecting the thin film transistor 60 and the capacitor 20.

A buffer layer 51 may be arranged between the substrate 10 and the thin film transistor 60.

A first insulating layer 52 may be arranged between the active layer 61 and the gate electrode 63 (e.g., along a thickness direction of the display apparatus 2), and a second insulating layer 53 may be arranged around and/or between (e.g., laterally) the gate electrode 63, the drain electrode 65, and the source electrode 67.

The emission device 70 may include a first electrode 71, a second electrode 75 arranged facing the first electrode 71, and an intermediate layer 73 arranged between the first electrode 71 and the second electrode 75 and including an organic emission layer. The first electrode 71 is arranged over a third insulating layer 54 covering the thin film transistor 60. The first electrode 71 is electrically connected to the drain electrode 65 or the source electrode 67 (the drain electrode 65 in the embodiment of FIG. 3). An edge of the first electrode 71 is covered with a pixel defining film 55.

The first electrode 71 may be formed in an independent island form for each pixel. The second electrode 75 may be formed in a thin film form having a thickness of several to tens of nanometers, and may be provided to be electrically connected across all pixels included in the organic light-emitting display apparatus 2.

The intermediate layer 73 may include an organic emission layer for emitting light, and at least one of a hole injection layer (HIL), a hole transport layer (HTL), an electron transport layer (ETL), and an electron injection layer (EIL) may be further arranged. However, the present disclosure is not limited thereto, and various functional layers may be further arranged between the first electrode 71 and the second electrode 75.

The organic emission layer may emit a red light, a green light, or a blue light. However, the present disclosure is not limited thereto, and the organic emission layer may emit a white light. In this case, the organic emission layer may include a structure in which an emission material emitting a red light, an emission material emitting a green light, and an emission material emitting a blue light are staked on one another, or a structure in which the emission material emitting a red light, the emission material emitting a green light, and the emission material emitting a blue light are mixed with one another.

The red, green, and blue lights are merely exemplary, and the present disclosure is not limited thereto. In other words, if a white light can be emitted, a combination of other various suitable colors other than the combination of red, green, and blue may be used.

The organic light-emitting display apparatus 2 according to the present embodiment may be of a top emission type that implements an image in a direction toward the second electrode 75, and a pixel circuit portion including the thin film transistor 60, the capacitor 20, etc. may be arranged overlapping the emission device 70 in a vertical direction (e.g., along a thickness direction of the display apparatus 2). In another embodiment, the organic light-emitting display apparatus 2 may be a bottom emission type that implements an image in a direction toward the first surface 11 of the substrate 10, and the pixel circuit portion including the thin film transistor 60, the capacitor 20, etc. may be arranged not overlapping the emission device 70.

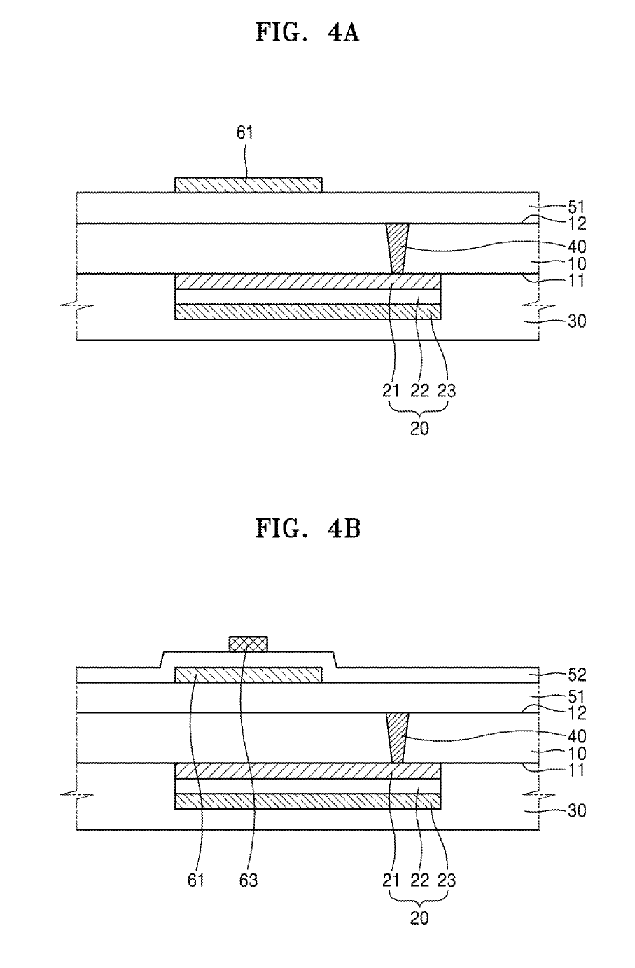

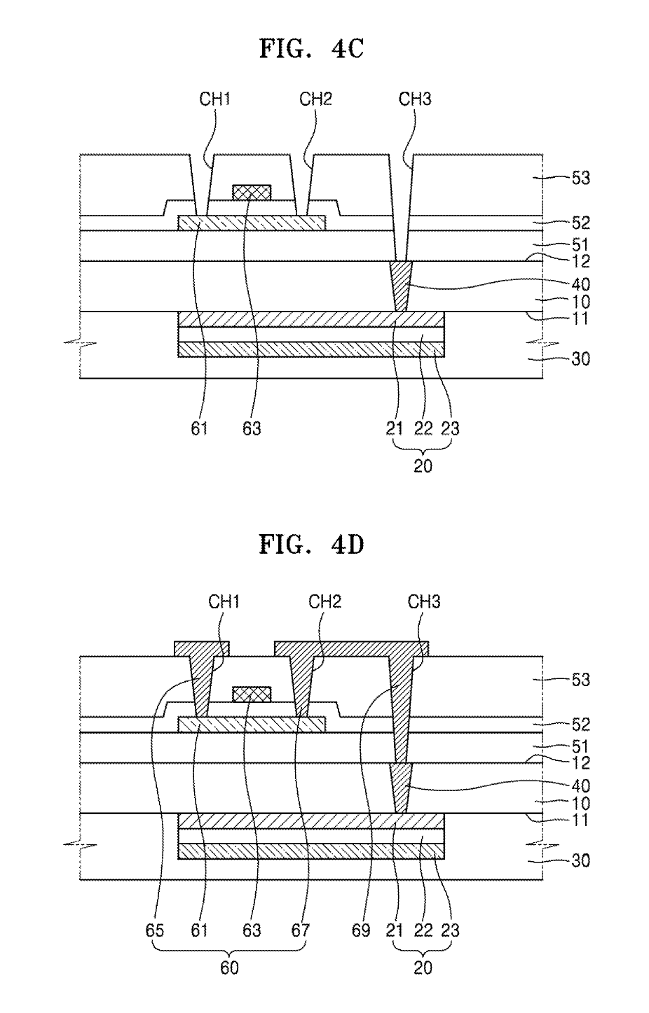

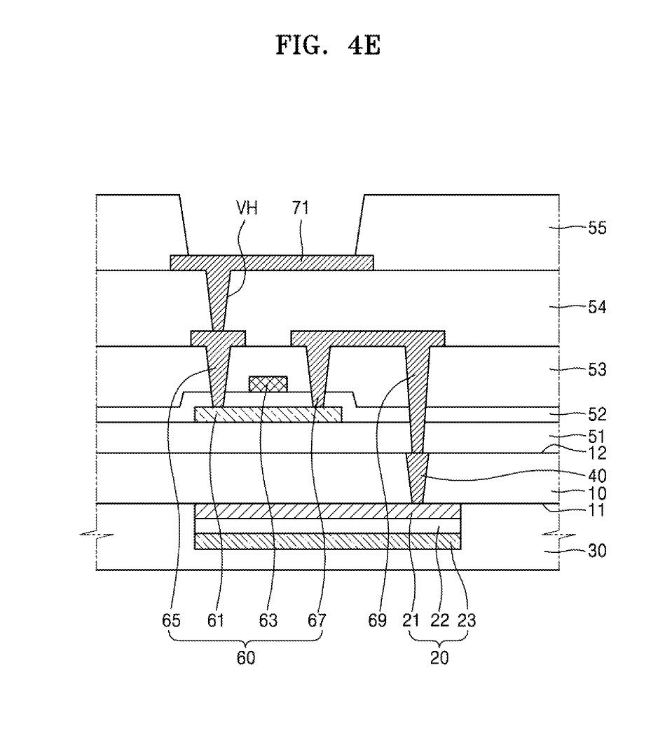

FIGS. 4A to 4E are cross-sectional views schematically illustrating a manufacturing process of the organic light-emitting display apparatus 2 according to the embodiment illustrated in FIG. 3.

Referring to FIG. 4A, the buffer layer 51 is formed on the second surface 12 of the substrate 10, in which the capacitor 20 is formed on the first surface 11 as a result of the process of FIGS. 2A to 2E, and then a semiconductor layer is formed on the buffer layer 51. The active layer 61 of the thin film transistor 60 is formed by patterning the semiconductor layer.

The buffer layer 51 performs functions of preventing or protecting from intrusion of impure elements into the substrate 10 and planarizing a surface. The buffer layer 51 may be formed of an inorganic material such as silicon nitride (SiNx) and/or silicon oxide (SiOx) in a single layer or a multilayer.

The semiconductor layer may include various materials. For example, the semiconductor layer may include an inorganic semiconductor material such as amorphous silicon or crystalline silicon. In another example, the semiconductor layer may include an oxide semiconductor or an organic semiconductor material.

Referring to FIG. 4B, the first insulating layer 52 is formed over the active layer 61, a third conductive layer is formed over the first insulating layer 52 and then patterned. Accordingly, the gate electrode 63 of the thin film transistor 60 may be formed.

The first insulating layer 52 may be formed as an inorganic insulating film of a single layer or a multilayer.

Referring to FIG. 4C, the second insulating layer 53 is formed over the gate electrode 63, and the buffer layer 51, the first insulating layer 52 and the second insulating layer 53 are patterned. Accordingly, contact holes CH1 and CH2 for exposing parts of the drain area and the source area of the active layer 61 may be formed in the first insulating layer 52 and the second insulating layer 53, and a contact hole CH3 for exposing a part of the conductive material 40 may be formed in the buffer layer 51, the first insulating layer 52 and the second insulating layer 53.

The second insulating layer 53, similarly to the first insulating layer 52, may be formed of an inorganic insulating film in a single layer or a multilayer.

Referring to FIG. 4D, a fourth conductive layer is formed over the second insulating layer 53 to fill the contact holes CH1, CH2, and CH3, and then patterned. Accordingly, the drain electrode 65 and the source electrode 67 of the thin film transistor 60 may be formed. The drain electrode 65 and the source electrode 67 may be electrically connected to both end portions of the active layer 61, that is, the drain area and the source area. Simultaneously or concurrently, the connection electrode 69 connecting the thin film transistor 60 (the source electrode 67 of the thin film transistor 60 in FIG. 4D) and the capacitor 20 may be formed.

Referring to FIG. 4E, the third insulating layer 54 is formed over the thin film transistor 60, and the third insulating layer 54 is patterned. Accordingly, a via hole VH for exposing a part of the drain electrode 65 of the thin film transistor 60 may be formed in the third insulating layer 54.

The third insulating layer 54 covers the pixel circuit portion including the thin film transistor 60.

The third insulating layer 54, similarly to the second insulating layer 53, may be formed of an inorganic insulating film in a single layer or a multilayer. In another embodiment, the third insulating layer 54 may be formed of an organic insulating film in a single layer or multilayer.

Next, a fifth conductive layer is formed over the third insulating layer 54, and the first electrode 71 of the emission device 70 is formed by patterning the fifth conductive layer. The first electrode 71 may be electrically connected to the drain electrode 65 of the thin film transistor 60 via the via hole VH. The first electrode 71 may be arranged to at least partially overlap the thin film transistor 60 and the capacitor 20.

Next, a fourth insulating layer is formed over the first electrode 71 of the emission device 70, and the pixel defining film 55 is formed by patterning the fourth insulating layer. The pixel defining film 55 may cover an edge of the first electrode 71 of each pixel.

The fourth insulating layer, similarly to the third insulating layer 54, may be formed of an organic insulating film in a single layer or a multilayer.

Then, the intermediate layer 73 of FIG. 3 and the second electrode 75 of FIG. 3 are formed over the first electrode 71, and the substrate 10 may be sealed with a sealing member. A capping layer and a filler may be provided between the substrate 10 and the sealing member.

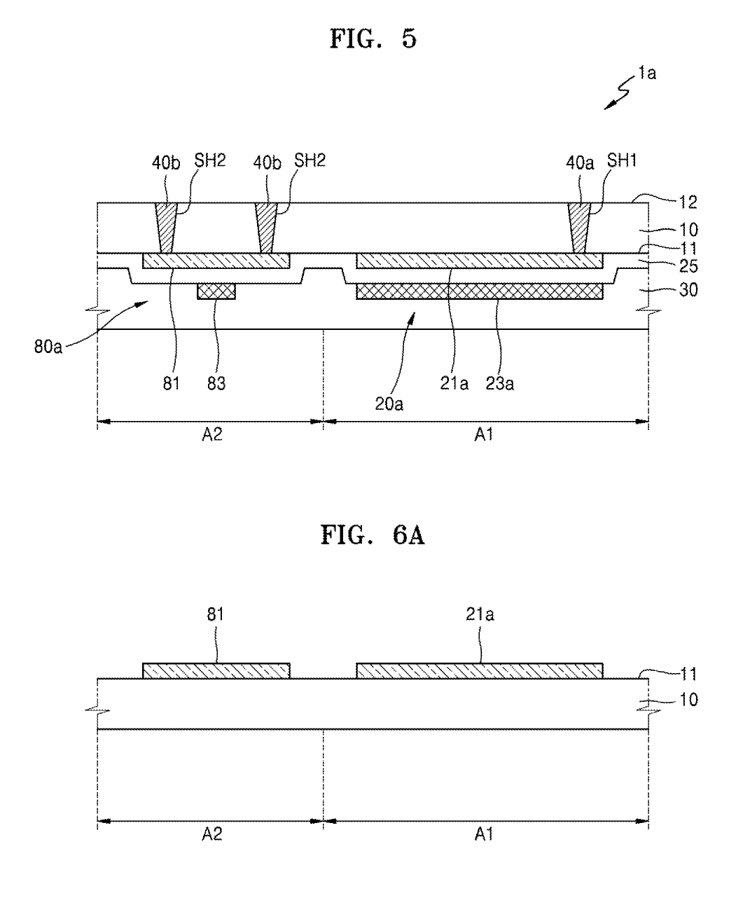

FIG. 5 is a cross-sectional view schematically illustrating a substrate apparatus 1a for a display apparatus according to another embodiment.

Referring to FIG. 5, the substrate apparatus 1a according to the present embodiment may include a capacitor 20a formed in a first area A1 of the first surface 11 of the substrate 10 and an element structure 80a formed in a second area A2 thereof.

The capacitor 20a may include a first electrode 21a and a second electrode 23a arranged above the first electrode 21a. An insulating layer 25 may function as a dielectric layer of the capacitor 20a between the first electrode 21a and the second electrode 23a.

The element structure 80a may include a first pattern layer 81 and a second pattern layer 83. The first pattern layer 81 may be a semiconductor layer including impurity doping areas at both end portions and a channel area between both impurity doping areas. The second pattern layer 83 may be an electrode layer of a conductive material.

The element structure 80a may be used as a thin film transistor in which the first pattern layer 81 and the second pattern layer 83 are respectively used as an active layer and a gate electrode. In this case, the insulating layer 25 may function as a gate insulating layer between the first pattern layer 81 and the second pattern layer 83.

The substrate 10 may be a substrate having various materials such as a glass material, a plastic material, and/or a metal material.

The substrate 10 may include a first hole SH1 for exposing a part of the first electrode 21a of the capacitor 20a and a second hole SH2 for exposing a part of each of both end portions of the first pattern layer 81.

The first hole SH1 and the second hole SH2 may be respectively filled with a first conductive material 40a and a second conductive material 40b. The first conductive material 40a may electrically connect the capacitor 20a and circuit elements formed on the second surface 12 of the substrate 10. The second conductive material 40b may electrically connect the element structure 80a and an element structure and/or the circuit elements formed on (e.g., above) the second surface 12 of the substrate 10.

The protection layer 30 that entirely covers the first surface 11 of the substrate 10 may be provided over the capacitor 20a and the element structure 80a.

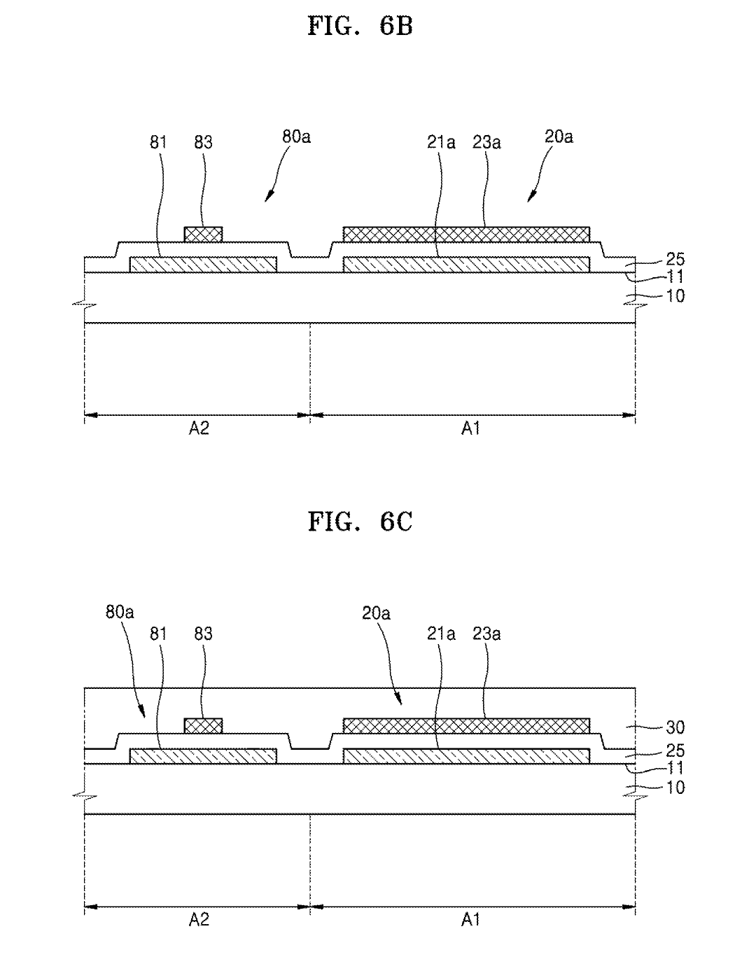

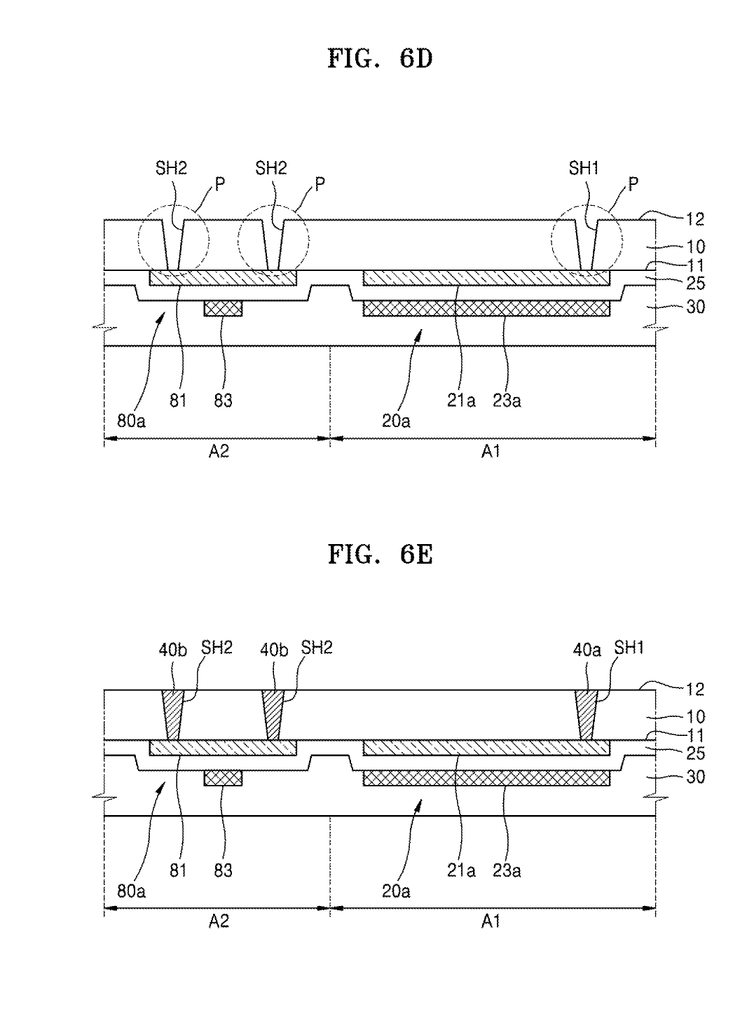

FIGS. 6A to 6E are cross-sectional views schematically illustrating a manufacturing process of the substrate apparatus 1a of FIG. 5.

Referring to FIG. 6A, the substrate 10 is prepared, and after the semiconductor layer is formed on the first surface 11 of the substrate 10, the semiconductor layer is patterned, thereby forming the first electrode 21a and the first pattern layer 81.

Although in FIG. 6A, the first electrode 21a and the first pattern layer 81 are formed of the same material, the present disclosure is not limited thereto. For example, after the semiconductor layer is formed on the first surface 11 of the substrate 10, the first pattern layer 81 is formed by patterning the semiconductor layer, and after a conductive layer is formed, the first electrode 21a may be formed by patterning the conductive layer. In this state, the formation sequence of the first electrode 21a and the first pattern layer 81 is not particularly limited.

Referring to FIG. 6B, the insulating layer 25 is formed over the first electrode 21a and the first pattern layer 81. After the conductive layer is formed over the insulating layer 25, the second electrode 23a and the second pattern layer 83 may be formed by patterning the conductive layer. Accordingly, the capacitor 20a may be formed in the first area A1, and the element structure 80a may be formed in the second area A2.

The insulating layer 25 may be formed of an inorganic insulating film in a single layer or a multilayer.

Referring to FIG. 6C, the protection layer 30 is formed over the second electrode 23a and the second pattern layer 83.

The protection layer 30 may be formed by a deposition and/or film lamination process using inorganic insulating material(s) and/or organic insulating material(s). The protection layer 30 may include a material that is the same as or different from the dielectric layer 22.

Referring to FIG. 6D, the substrate 10 is reversed, and the first hole SH1 and the second hole SH2 are formed in the substrate 10.

The first hole SH1 and the second hole SH2 may be formed by irradiating a laser beam onto the area P of the second surface 12 of the substrate 10 that is reversed. The first hole SH1 and the second hole SH2 may be formed by using, for example, a laser drill technique. The first hole SH1 may be formed with a certain diameter by penetrating through the substrate 10 to expose a part of the first electrode 21 of the capacitor 20. The second hole SH2 may be formed with a certain diameter by penetrating through the substrate 10 to expose both end portions of the first pattern layer 81.

Referring to FIG. 6E, the first hole SH1 and the second hole SH2 of the substrate 10 may be filled with the first conductive material 40a and the second conductive material 40b, respectively. The first conductive material 40a and the second conductive material 40b may be the same material or different materials.

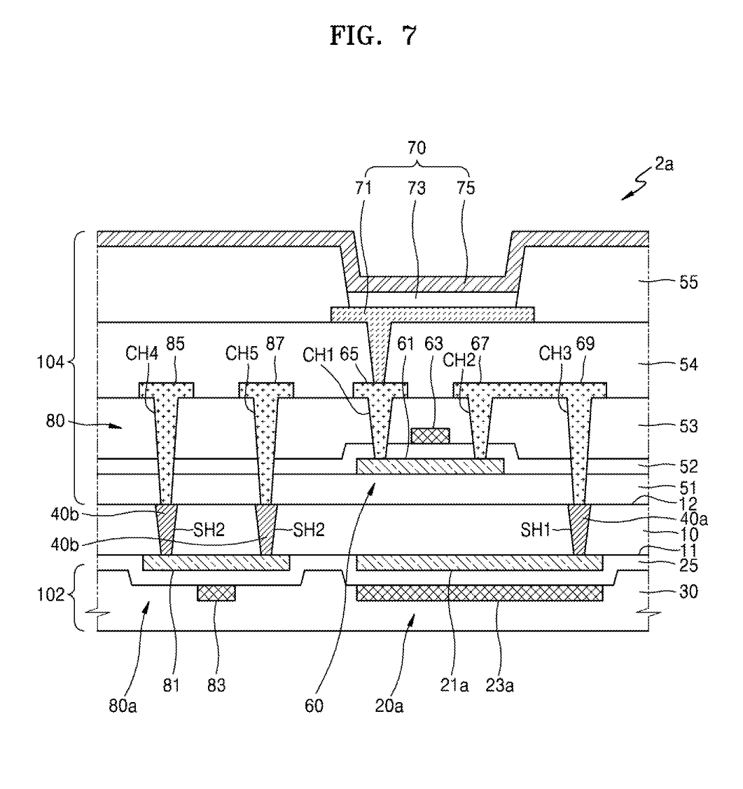

FIG. 7 is a cross-sectional view schematically illustrating an organic light-emitting display apparatus 2A using the substrate apparatus 1a of FIG. 5.

Referring to FIG. 7, the organic light-emitting display apparatus 2A according to the present embodiment may include the substrate 10, a first device layer 102 on the first surface 11 of the substrate 10, and a second device layer 104 on the second surface 12 of the substrate 10.

The first conductive material 40a and the second conductive material 40b filled in the first hole SH1 and the second hole SH2 may be provided in the substrate 10. The first conductive material 40a and the second conductive material 40b may electrically connect elements of the first device layer 102 and elements of the second device layer 104.

The first device layer 102 may include the capacitor 20a and the element structure 80a. The protection layer 30 that entirely covers the first surface 11 of the substrate 10 may be provided over the capacitor 20a and the element structure 80a.

The capacitor 20a may include the first electrode 21a, the second electrode 23a, and the insulating layer 25 between the first electrode 21a and the second electrode 23a.

The element structure 80a may include the first pattern layer 81 and the second pattern layer 83.

The first electrode 21a of the capacitor 20a and the first pattern layer 81 of the element structure 80a may include the same material or different materials.

The second device layer 104 may include the thin film transistor 60 and the emission device 70.

The thin film transistor 60 may include the active layer 61, the gate electrode 63, the drain electrode 65, and the source electrode 67. The drain electrode 65 and the source electrode 67 are electrically connected to the drain area and the source area of the active layer 61, respectively. The connection electrode 69 extending from one electrode (e.g., the source electrode 67 in FIG. 7) of the thin film transistor 60 comes in contact with the first conductive material 40a, thereby electrically connecting the thin film transistor 60 and the capacitor 20a.

The buffer layer 51 may be arranged between the substrate 10 and the thin film transistor 60. The first insulating layer 52 may be arranged between the active layer 61 and the gate electrode 63, and the second insulating layer 53 may be arranged between the gate electrode 63, the drain electrode 65, and the source electrode 67.

The drain electrode 65 and the source electrode 67 may be electrically connected to the active layer 61, respectively via the contact holes CH1 and CH2 formed in the first insulating layer 52 and the second insulating layer 53 and exposing parts of both end portions of the active layer 61. The connection electrode 69 comes in contact with the first conductive material 40a via the contact hole CH3 formed in the buffer layer 51, the first insulating layer 52, and the second insulating layer 53 and exposing a part of the first conductive material 40a. Accordingly, the connection electrode 69 may electrically connect the thin film transistor 60 and the capacitor 20a.

The emission device 70 may include the first electrode 71, the second electrode 75 facing the first electrode 71, and the intermediate layer 73 arranged between the first electrode 71 and the second electrode 75 and including an organic emission layer. The first electrode 71 is arranged on the third insulating layer 54 and electrically connected to the drain electrode 65 or the source electrode 67 (the drain electrode 65 in the embodiment of FIG. 7). An edge of the first electrode 71 is covered with the pixel defining film 55.

A second thin film transistor 80 may be provided across the first device layer 102 and the second device layer 104.

The second thin film transistor 80 may include the first pattern layer 81 and the second pattern layer 83 provided over the first surface 11 of the substrate 10, respectively as an active layer and a gate electrode, and include a drain electrode 85 and a source electrode 87 provided on (e.g., above) the second surface 12 of the substrate 10.

The drain electrode 85 and the source electrode 87 come in contact with the second conductive material 40b, respectively via contact holes CH4 and CH5 formed in the buffer layer 51, the first insulating layer 52, and the second insulating layer 53 and exposing a part of the second conductive material 40b. Accordingly, the drain electrode 85 and the source electrode 87 may be electrically connected to both end portions of the first pattern layer 81.

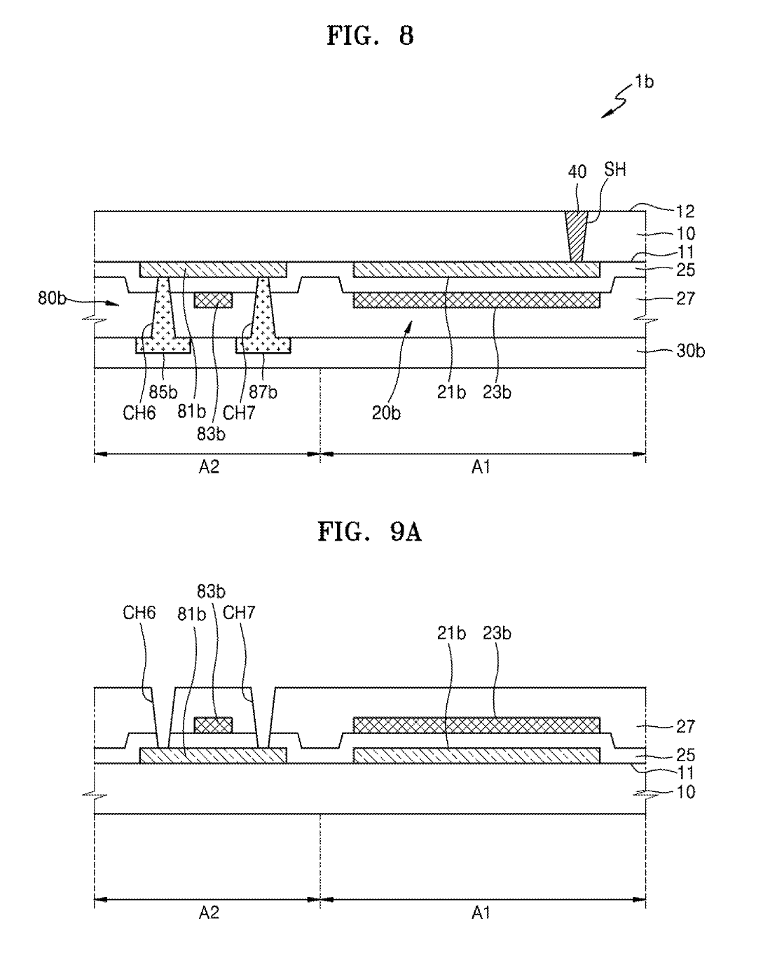

FIG. 8 is a cross-sectional view schematically illustrating a substrate apparatus 1b for a display apparatus according to another embodiment.

Referring to FIG. 8, the substrate apparatus 1b according to the present embodiment may include a capacitor 20b formed in the first area A1 of the first surface 11 of the substrate 10 and a third thin film transistor 80b formed in the second area A2.

The capacitor 20b may include a first electrode 21b and a second electrode 23b above the first electrode 21b. The insulating layer 25 may function as a dielectric layer of the capacitor 20b between the first electrode 21b and the second electrode 23b.

The third thin film transistor 80b may include an active layer 81b, a gate electrode 83b, a drain electrode 85b, and a source electrode 87b. The drain electrode 85b and the source electrode 87b come in contact with a drain area and a source area of the active layer 81b via a sixth contact hole CH6 and a seventh contact hole CH7.

The insulating layer 25 may function as a gate insulating layer between the active layer 81b and the gate electrode 83b. An insulating layer 27 functions as an interlayer insulating layer between the gate electrode 83b, and the drain electrode 85b and the source electrode 87b.

A protection layer 30b that entirely covers the first surface 11 of the substrate 10 may be provided above the capacitor 20b and the third thin film transistor 80b.

The substrate 10 may be a substrate having various materials such as a glass material, a plastic material, or a metal material.

The substrate 10 may include the hole SH for exposing a part of the first electrode 21b of the capacitor 20b.

The hole SH may be filled with the conductive material 40. The conductive material 40 may electrically connect the capacitor 20b and the circuit elements formed on the second surface 12 of the substrate 10.

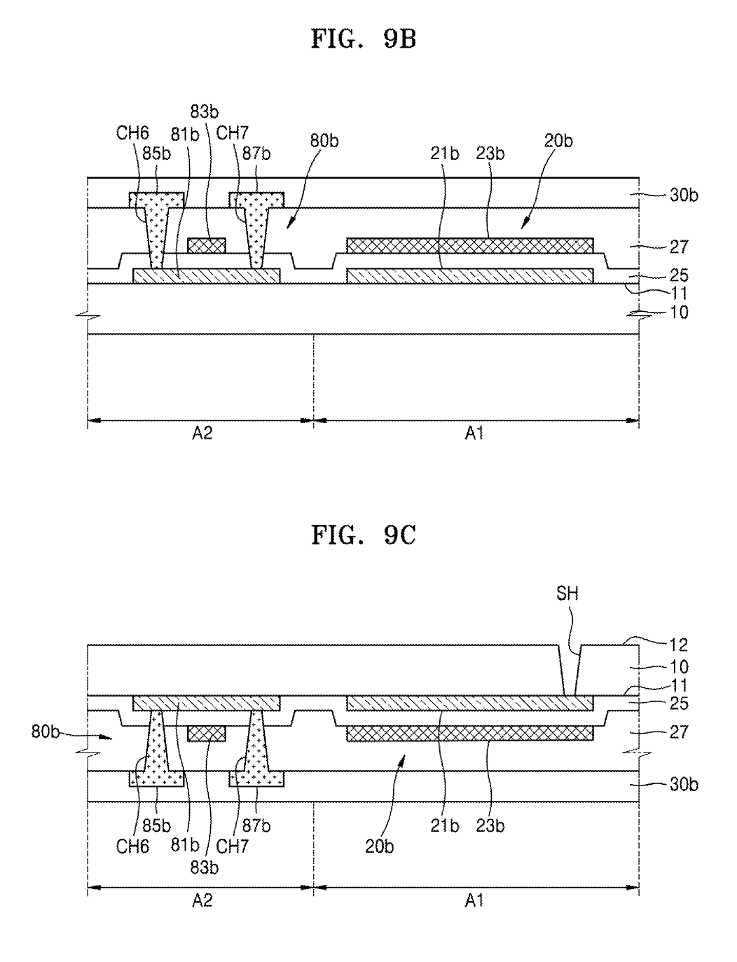

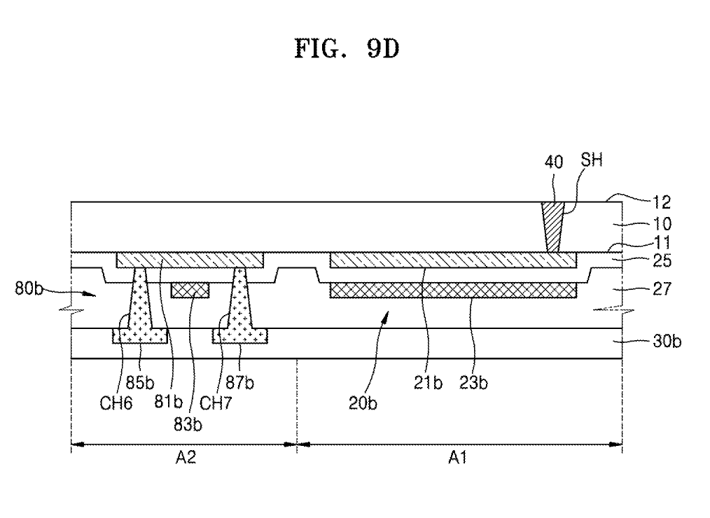

FIGS. 9A to 9D are cross-sectional views schematically illustrating a manufacturing process of the substrate apparatus 1b of FIG. 8.

Referring to FIG. 9A, as illustrated in FIGS. 6A and 6B, the substrate 10 is prepared, after the semiconductor layer is formed on the first surface 11 of the substrate 10, the first electrode 21b and the active layer 81b may be respectively formed in the first area A1 and the second area A2 by patterning the semiconductor layer. In another embodiment, after the semiconductor layer is formed on the first surface 11 of the substrate 10, the active layer 81b is formed by patterning the semiconductor layer. After the conductive layer is formed, the first electrode 21b may be formed by patterning the conductive layer. In this state, the formation sequence of the first electrode 21b and the active layer 81b is not particularly limited.

Next, the insulating layer 25 is formed over the first electrode 21b and the active layer 81b, and after the conductive layer is formed over the insulating layer 25, the second electrode 23b and the gate electrode 83b may be formed by patterning the conductive layer.

Next, the insulating layer 27 is formed over the second electrode 23b and the gate electrode 83b, and the sixth contact hole CH6 and the seventh contact hole CH7 for exposing parts of the drain area and the source area of the active layer 81b are formed in the insulating layer 27 of the second area A2.

Referring to FIG. 9B, after the conductive layer is formed over the insulating layer 27, the drain electrode 85b and the source electrode 87b are formed in the second area A2 by patterning conductive layer. The drain electrode 85b and the source electrode 87b come in contact with the drain area and the source area of the active layer 81b via the sixth contact hole CH6 and the seventh contact hole CH7. Accordingly, the capacitor 20b may be formed in the first area A1, and the third thin film transistor 80b may be formed in the second area A2.

The insulating layers 25 and 27 may be formed of an inorganic insulating film in a single layer or a multilayer.

The protection layer 30b is formed over the drain electrode 85b and the source electrode 87b.

Referring to FIG. 9C, the substrate 10 is reversed, and the hole SH is formed in the substrate 10.

The hole SH may be formed by using, for example, a laser drill technique. Various pulse lasers may be used for a laser drilling method. The hole SH may be formed with a certain diameter by penetrating through the substrate 10 to expose a part of the first electrode 21b of the capacitor 20b.

Referring to FIG. 9D, the hole SH of the substrate 10 may be filled with the conductive material 40.

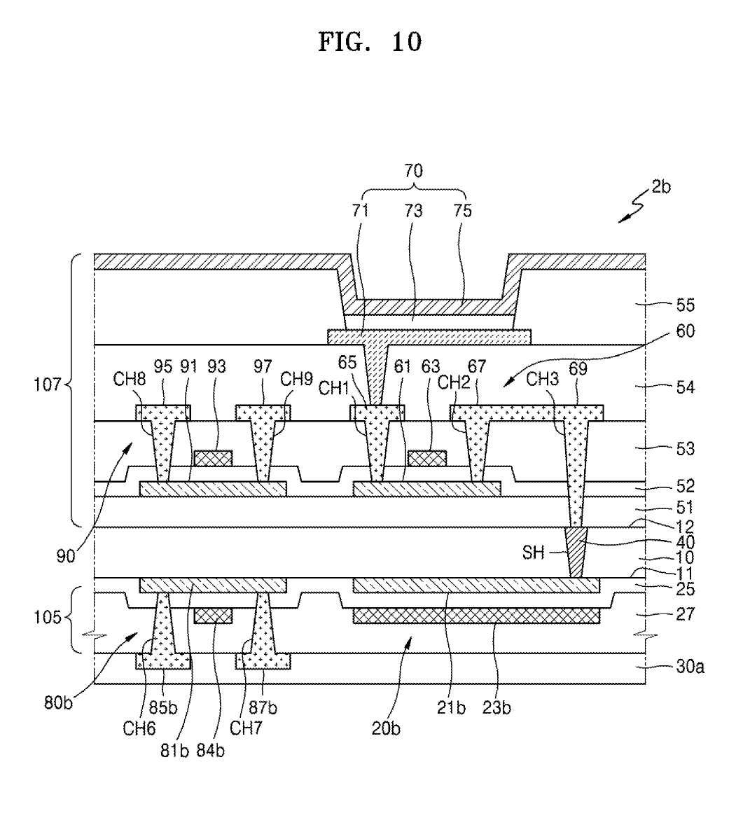

FIG. 10 is a cross-sectional view schematically illustrating a part of an organic light-emitting display apparatus 2b using the substrate apparatus of FIG. 8.

Referring to FIG. 10, the organic light-emitting display apparatus 2b according to the present embodiment may include the substrate 10, a first device layer 105 provided on the first surface 11 of the substrate 10, a second device layer 107 provided on the second surface 12 of the substrate 10.

The substrate 10 may include the conductive material 40 filled in the hole SH. The conductive material 40 may electrically connect elements of the first device layer 105 and elements of the second device layer 107.

The first device layer 102 may include the capacitor 20b and the third thin film transistor 80b.

The capacitor 20b may include the first electrode 21b and the second electrode 23b. The insulating layer 25 may function as a dielectric layer between the first electrode 21b and the second electrode 23b.

The third thin film transistor 80b may include the active layer 81b, the gate electrode 83b, the drain electrode 85b, and the source electrode 87b. The drain electrode 85b and the source electrode 87b are electrically connected to the drain area and the source area of the active layer 81b, respectively via the sixth contact hole CH6 and the seventh contact hole CH7.

The second device layer 107 may include the thin film transistor 60, a fourth thin film transistor 90, and the emission device 70.

The thin film transistor 60 may include the active layer 61, the gate electrode 63, the drain electrode 65, and the source electrode 67. The drain electrode 65 and the source electrode 67 may be electrically connected to the active layer 61 via the contact holes CH1 and CH2 formed in the first insulating layer 52 and the second insulating layer 53 and exposing parts of both end portions of the active layer 61. The connection electrode 69 comes in contact with the conductive material 40 via the contact hole CH3 formed in the buffer layer 51, the first insulating layer 52, and the second insulating layer 53 and exposing a part of the conductive material 40. Accordingly, the connection electrode 69 may electrically connect the thin film transistor 60 and the capacitor 20b.

The fourth thin film transistor 90 may include an active layer 91, a gate electrode 93, a drain electrode 95, and a source electrode 97. The drain electrode 95 and the source electrode 97 may be electrically connected to the active layer 91 via contact holes CH8 and CH9 formed in the first insulating layer 52 and the second insulating layer 53 and exposing parts of both end portions of the active layer 91.

The emission device 70 may include the first electrode 71, the second electrode 75 facing the first electrode 71, and the intermediate layer 73 arranged between the first electrode 71 and the second electrode 75 and including an organic emission layer.

In the embodiments of FIGS. 9 and 10, a double-sided emission display apparatus may be implemented as a thin film transistor is provided at each of the first surface 11 and the second surface 12 of the substrate 10, or a modification is possible such that a sensor is arranged on (e.g., below) the first surface 11 and a display apparatus is implemented on (e.g., above) the second surface 12.

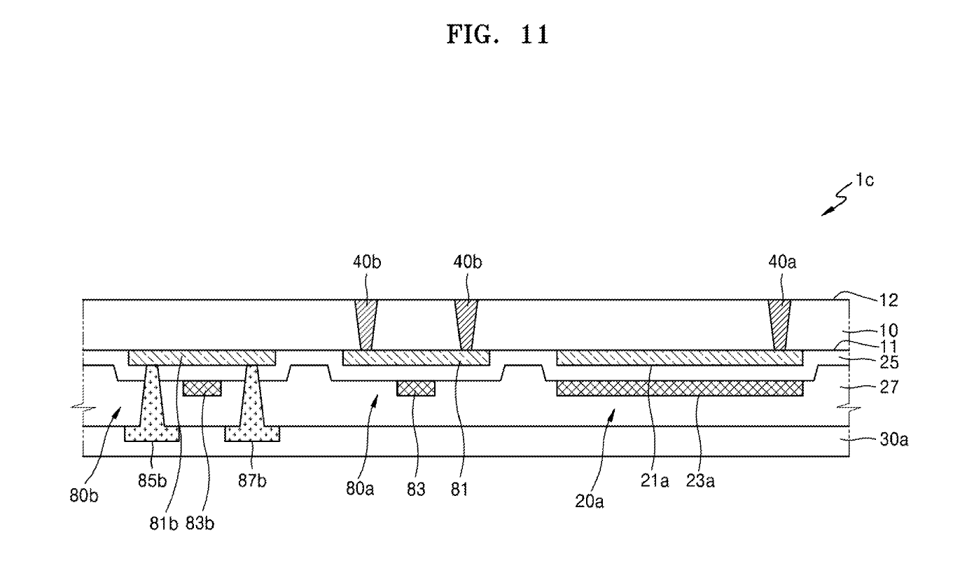

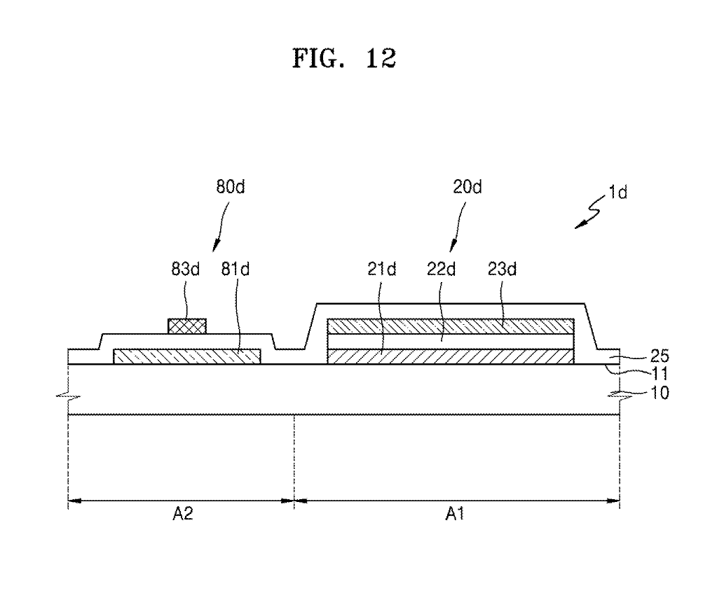

FIGS. 11 and 12 are cross-sectional views schematically illustrating substrate apparatus 1c and 1 d for a display apparatus according to other embodiments.

The embodiment of FIG. 11 is a modified example in which the capacitor 20a and the element structure 80a illustrated in FIG. 5 and the third thin film transistor 80b illustrated in FIG. 8 are provided on the first surface 11 of the substrate 10. An organic light-emitting display may be manufactured by using the substrate 1c (for a display apparatus illustrated in FIG. 11).

The embodiment of FIG. 12 is different from the above-described embodiment, in which the first electrode of the capacitor and the first pattern layer of the element structure or the active layer of the thin film transistor are simultaneously or concurrently formed, in that an element structure 80d is formed after a capacitor 20d is formed on the first surface 11 of the substrate 10.

Referring to FIG. 12, as illustrated in FIGS. 2A and 2B, a first electrode 21d, a dielectric layer 22d, and a second electrode 23d are sequentially deposited on the first surface 11 of the substrate 10 and then patterned to form the capacitor 20d including the first electrode 21d, the dielectric layer 22d, and the second electrode 23d in the first area A1.

Next, a semiconductor layer is formed on the second area A2 and then patterned to form a first pattern layer 81d. The insulating layer 25 is formed entirely over the first surface 11 of the substrate 10. Next, a conductive layer is formed on the insulating layer 25 and then patterned to form a second pattern layer 83d.

Next, an insulating layer is formed over the second pattern layer 83d to form the element structure 80d, or a thin film transistor may be formed by adding a drain electrode and a source electrode.

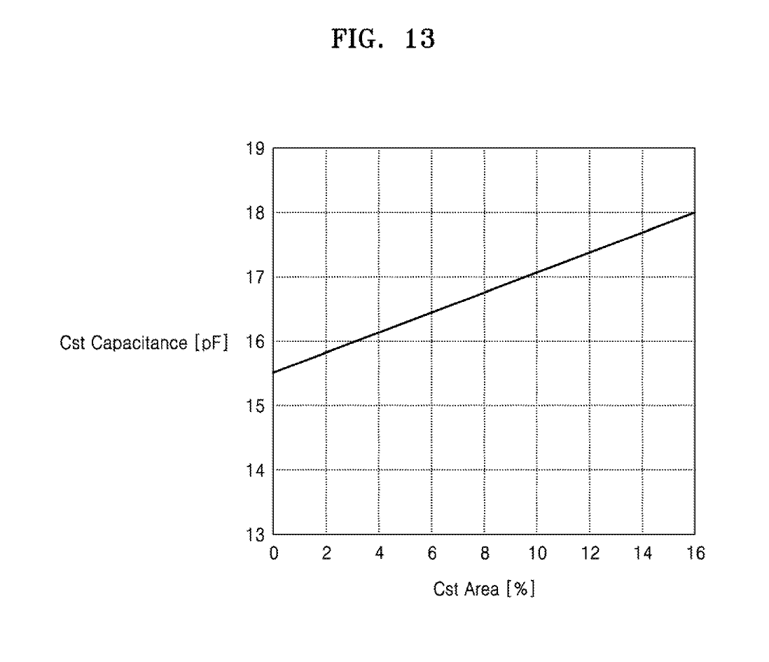

FIG. 13 is a graph showing a relationship between an increase in the area of a capacitor by calculation and the capacitance of a capacitor. Referring to FIG. 13, as the area of a capacitor increases, the capacitance of the capacitor increases. As the capacitance of a capacitor increases, a display apparatus may maintain a stable emission state.

In an organic light-emitting display apparatus, a storage capacitor stores a data voltage and retains emission of a pixel for one frame. As the capacitance of a storage capacitor increases, stable emission may be maintained. As a resolution increases, a pixel size of an organic light-emitting display apparatus decrease, and thus the size of a storage capacitor is restricted.

In the embodiments of the present disclosure, because a storage capacitor is formed on a surface opposite to a surface where circuit elements are formed, and a conductive passage is formed in the substrate by the laser drill technique, the area of a capacitor may be increased without being restricted by an active area. Accordingly, a sufficient capacitance of a storage capacitor may be secured, and thus a process margin may be increased and stable device manufacture may be possible.

In the embodiments of the present disclosure, since the capacitor, the thin film transistor, and other elements are formed on both surfaces of the substrate by freely modifying the same according to the pixel size and purposes thereof, various display apparatuses may be implemented.

As described above, according to the embodiments of the present disclosure, since the capacitance of a capacitor is sufficiently secured and thus stable emission may be maintained, a high-resolution display apparatus with improved display quality may be provided.

Expressions such as “at least one of”, “one of” or “selected from” when preceding a list of elements, modify the entire list of elements and do not modify the individual elements of the list. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another element or layer, there are no intervening elements or layers present.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A substrate apparatus for a display apparatus comprising:
a substrate; and
a capacitor on a first surface of the substrate, the capacitor including a first electrode, a second electrode facing the first electrode, and a dielectric layer between the first electrode and the second electrode,
wherein the substrate has a first hole penetrating through the substrate in an area corresponding to a part of the first electrode of the capacitor, and a first conductive material is in the first hole.

2. The substrate apparatus of claim 1, further comprising:
a first pattern layer and a second pattern layer on the first surface of the substrate, the first pattern layer being at a same level as the first electrode of the capacitor and the second pattern layer being at a same level as the second electrode of the capacitor,
wherein the substrate further has a second hole penetrating through the substrate in an area corresponding to a part of each of both end portions of the first pattern layer, and a second conductive material is in the second hole.

3. The substrate apparatus of claim 2, wherein the first pattern layer includes a semiconductor material.

4. The substrate apparatus of claim 2, further comprising an insulating layer between the first pattern layer and the second pattern layer,
wherein the insulating layer includes a material that is the same as or different from the dielectric layer of the capacitor.

5. The substrate apparatus of claim 1, further comprising:
an active layer on the first surface of the substrate at a same level as the first electrode of the capacitor;
a gate electrode over the active layer; and
a source electrode and a drain electrode connected to both end portions of the active layer, respectively.

6. The substrate apparatus of claim 1, further comprising a protection layer covering the capacitor.

7. An organic light-emitting display apparatus comprising:
a substrate;
a capacitor on a first surface of the substrate, the capacitor including a first electrode, a second electrode facing the first electrode, and a dielectric layer between the first electrode and the second electrode; and
a first thin film transistor on a second surface, opposite to the first surface, of the substrate, the first thin film transistor including a first active layer, a first gate electrode, and a first source electrode and a first drain electrode connected to both end portions of the first active layer, respectively,
wherein the substrate has a first hole penetrating through the substrate in an area corresponding to a part of the first electrode of the capacitor, and a first conductive material is in the first hole,
wherein the organic light-emitting display apparatus further comprises a connection electrode electrically connecting one of the first source electrode and the first drain electrode of the first thin film transistor and the first conductive material in the substrate.

8. The organic light-emitting display apparatus of claim 7, wherein the connection electrode extends from the one of the first source electrode and the first drain electrode of the first thin film transistor.

9. The organic light-emitting display apparatus of claim 7, wherein the capacitor overlaps at least a part of the first thin film transistor.

10. The organic light-emitting display apparatus of claim 7, further comprising a second thin film transistor including, on the first surface of the substrate, a second active layer at a same level as the first electrode of the capacitor and a second gate electrode at a same level as the second electrode of the capacitor, and on the second surface of the substrate, a second source electrode and a second drain electrode connected to both end portions of the second active layer, respectively,
wherein the substrate includes a second hole penetrating through the substrate in an area corresponding to a part of each of both end portions of the second active layer, and a second conductive material in the second hole,
wherein the second source electrode and the second drain electrode come in contact with the second conductive material.

11. The organic light-emitting display apparatus of claim 10, further comprising an insulating layer between the second active layer and the second gate electrode,
wherein the insulating layer includes a material that is the same as or different from the dielectric layer of the capacitor.

12. The organic light-emitting display apparatus of claim 7, further comprising a third thin film transistor including, on the first surface of the substrate, a third active layer at a same level as the first electrode of the capacitor, a third gate electrode at a same level as the second electrode of the capacitor, and a third source electrode and a third drain electrode connected to both end portions of the third active layer, respectively.

13. The organic light-emitting display apparatus of claim 7, further comprising an emission device arranged above the first thin film transistor and including a first electrode, a second electrode facing the first electrode, and an organic light-emitting layer between the first electrode and the second electrode.

14. A method of manufacturing an organic light-emitting display apparatus, the method comprising:
preparing a substrate;
forming, on a first surface of the substrate, a capacitor including a first electrode, a second electrode facing the first electrode, and a dielectric layer between the first electrode and the second electrode;
reversing the substrate, and forming a first hole penetrating through the substrate in an area corresponding to a part of the first electrode of the capacitor; and
filling a first conductive material in the first hole.

15. The method of claim 14, wherein the first hole is formed by a laser drill technique.

16. The method of claim 14, further comprising:
forming, on a second surface, opposite to the first surface, of the substrate, a first thin film transistor including a first active layer, a first gate electrode, and a first source electrode and a first drain electrode connected to both end portions of the first active layer, respectively; and
forming a connection electrode connecting one of the first source electrode and the first drain electrode of the first thin film transistor and the first conductive material in the substrate.

17. The method of claim 14, further comprising:
forming, on the first surface of the substrate, a first pattern layer at a same level as the first electrode of the capacitor and a second pattern layer at a same level as the second electrode of the capacitor;
reversing the substrate, and forming a second hole penetrating through the substrate in an area corresponding to a part of each of both end portions of the first pattern layer; and
filling a second conductive material in the second hole.

18. The method of claim 17, wherein the second hole is formed by a laser drill technique.

19. The method of claim 17, further comprising forming, on a second surface, opposite to the first surface, of the substrate, an electrode layer contacting each of both end portions of the first pattern layer.

20. The method of claim 14, further comprising forming, on the first surface of the substrate, an active layer at a same level as the first electrode of the capacitor, a second gate electrode at a same level as the second electrode of the capacitor, and a source electrode and a drain electrode connected to both end portions of the active layer, respectively.
